(19) United States
(12) Patent Application Publication
(10) Pub. No.: US 2025/0062301 A1
(43) Pub. Date: Feb. 20, 2025

(54) DISPLAY DEVICE

(71) Applicant: Samsung Display Co., LTD., Yongin-si (KR)

(72) Inventors: Ji Hye HAN, Yongin-si (KR); Chul Min BAE, Yongin-si (KR); Jae Hee SEO, Yongin-si (KR)

(21) Appl. No.: 18/656,457

(22) Filed: May 6, 2024

(30) Foreign Application Priority Data
Aug. 17, 2023 (KR) 10-2023-0107485

(51) Int. Cl. H01L 25/16; G09G 3/3233

(52) U.S. Cl. CPC H01L 25/167; G09G 3/3233; G09G 2300/0426; G09G 2300/0819; G09G 2300/0842

(57) ABSTRACT

A display device includes: a substrate; a first electrode and a second electrode on the substrate, extended in a first direction and spaced apart from each other; a first insulating layer on the first electrode and the second electrode; a light-emitting element on the first insulating layer and between the first electrode and the second electrode; and a first connection electrode connected to a first end of the light-emitting element and a second connection electrode connected to a second end of the light-emitting element, wherein the first insulating layer overlaps with the light-emitting element and comprises trench portions comprising a plurality of trenches.

### CROSS-REFERENCED TO RELATED APPLICATION

The present application claims priority to and the benefit of Korean Patent Application No. 10-2023-0107485, filed on Aug. 17, 2023, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

Display devices have become more and more important as multimedia technology evolves. Accordingly, a variety of types of display devices such as organic light-emitting display (OLED) devices and liquid crystal display (LCD) devices may be utilized.

As a display device for displaying images, there is a self-luminous display device including light-emitting elements. Examples of such self-luminous display devices may include organic light-emitting display devices using an organic material as the light-emitting material for the light-emitting elements, or inorganic light-emitting display devices using an inorganic material as the light-emitting material for the light-emitting elements.

The above information disclosed in this Background section is only for enhancement of understanding of the background and therefore the information discussed in this Background section does not necessarily constitute prior art.

### SUMMARY

Aspects of some embodiments of the present disclosure include a display device that can prevent or reduce a seam in a first insulating layer due to level differences created by electrodes and can relatively improve the alignment of light-emitting elements.

It should be noted that characteristics of embodiments according to the present disclosure are not limited to the above-mentioned characteristics; and other characteristics of embodiments according to the present disclosure will be more apparent to those skilled in the art from the following descriptions.

According to some embodiments of the present disclosure, a display device comprises a substrate, a first electrode and a second electrode on the substrate, extended in a first direction and spaced apart from each other, a first insulating layer on the first electrode and the second electrode, a light-emitting element on the first insulating layer and between the first electrode and the second electrode, and a first connection electrode connected to a first end of the light-emitting element and a second connection electrode connected to a second end of the light-emitting element, wherein the first insulating layer overlaps with the light-emitting element and comprises trench portions comprising a plurality of trenches.

According to some embodiments, the trench portions comprise a first trench portion overlapping with the first end of the light-emitting element, and a second trench portion overlapping with the second end of the light-emitting element.

According to some embodiments, the first trench portion overlaps with the first electrode and is extended in parallel with the first electrode, and wherein the second trench portion overlaps with the second electrode and is extended in parallel with the second electrode.

According to some embodiments, a side of the first trench portion is aligned with and coincides with a side of the first end of the light-emitting element, and a side of the second trench portion is aligned with and coincides with a side of the second end of the light-emitting element.

According to some embodiments, the trench portions are in contact with a lower surface of the light-emitting element.

According to some embodiments, a depth of the trenches is 1% to 30% of a thickness of the first insulating layer.

According to some embodiments, the first insulating layer contains silicon oxynitride represented by the following chemical formula:

SixOyNz

wherein x, y and z satisfy 34.6<x<42.9, 24.2<y<63.8 and 1.5<z<32.9, respectively, and x, y and z denote atomic ratios.

According to some embodiments, a thickness of the first insulating layer ranges from 2,000 Å to 3,000 Å.

According to some embodiments, a refractive index of the first insulating layer is greater than 1.4 and less than 1.63.

According to some embodiments, the display device further comprises a second insulating layer on the light-emitting element, wherein an etch selectivity of the first insulating layer with respect to the second insulating layer is 4.1 or more than.

According to some embodiments of the present disclosure, a display device comprises a substrate, a first electrode and a second electrode on the substrate, extended in a first direction and spaced apart from each other, a first insulating layer on the first electrode and the second electrode, a light-emitting element on the first insulating layer and between the first electrode and the second electrode, and a first connection electrode connected to a first end of the light-emitting element and a second connection electrode connected to a second end of the light-emitting element, wherein the first insulating layer overlaps with the light-emitting element and comprises protrusion portions comprising a plurality of protrusions.

According to some embodiments, the protrusion portions comprise a first protrusion portion overlapping with the first end of the light-emitting element, and a second protrusion portion overlapping with the second end of the light-emitting element.

According to some embodiments, the first protrusion portion overlaps with the first electrode and is extended in parallel with the first electrode, and wherein the second protrusion portion overlaps with the second electrode and is extended in parallel with the second electrode.

According to some embodiments, a side of the first protrusion portion is aligned with and coincides with a side of the first end of the light-emitting element, and a side of the second protrusion portion is aligned with and coincides with a side of the second end of the light-emitting element.

According to some embodiments, the protrusion portions are in contact with a lower surface of the light-emitting element.

According to some embodiments, a height of the protrusions is 1% to 30% of a thickness of the first insulating layer.

According to some embodiments, the first insulating layer contains silicon oxynitride represented by the following chemical formula:

SixOyNz

wherein x, y and z satisfy 34.6<x<42.9, 24.2<y<63.8 and 1.5<z<32.9, respectively, and x, y and z denote atomic ratios.

According to some embodiments, a thickness of the first insulating layer ranges from 2,000 Å to 3,000 Å.

According to some embodiments, a refractive index of the first insulating layer is greater than 1.4 and less than 1.63.

According to some embodiments, the display device further comprises a second insulating layer on the light-emitting element, wherein an etch selectivity of the first insulating layer with respect to the second insulating layer is 4.1 or more than.

According to some embodiments of the present disclosure, a first insulating layer containing silicon oxynitride having the composition ratios of Chemical Formula 1 is formed in a display device, so that it may be possible to prevent or reduce a seam on side surfaces of electrodes, to facilitate alignment of the light-emitting elements, and to relatively improve the emission efficiency.

In addition, by forming trench portions or protrusion portions in the first insulating layer, it may be possible to improve the alignment of the light-emitting elements.

It should be noted that characteristics of embodiments according to the present disclosure are not limited to those described above and other characteristics of embodiments according to the present disclosure will be more apparent to those skilled in the art from the following descriptions.

### BRIEF DESCRIPTION OF THE DRAWINGS

The above and other aspects and features of the present disclosure will become more apparent by describing in more detail aspects of some embodiments thereof with reference to the attached drawings, in which:

FIG. 1 is a plan view of a display device according to some embodiments of the present disclosure.

FIG. 2 is a plan view showing arrangement of a plurality of lines included in a display device according to some embodiments of the present disclosure.

FIG. 3 is an equivalent circuit diagram of a sub-pixel according to some embodiments of the present disclosure.

FIG. 4 is a plan view showing a pixel of a display device according to some embodiments of the present disclosure.

FIG. 5 is a cross-sectional view taken along the line E1-E1′ of FIG. 4.

FIG. 6 is a cross-sectional view taken along the line E2-E2′ of FIG. 4.

FIG. 7 is an enlarged view of the area A shown in FIG. 5.

FIG. 8 is a plan view showing the area A of FIG. 5.

FIG. 9 is a cross-sectional view showing a first insulating layer of a display device according to some embodiments.

FIG. 10 is a view showing a light-emitting element according to some embodiments of the present disclosure.

FIG. 11 is a cross-sectional view showing a display device according to some embodiments of the present disclosure.

FIG. 12 is an enlarged view of a portion of FIG. 11.

FIG. 13 is a view showing protrusions of a first insulating layer.

FIG. 14 is a cross-sectional view showing a display device according to some embodiments of the present disclosure.

FIG. 15 is an image taken by a transmission electron microscope according to Comparative Example 1.

FIG. 16 is an image taken by the transmission electron microscope according to Comparative Example 2.

FIG. 17 is an image taken by the transmission electron microscope according to Comparative Example 3.

FIG. 18 is an image taken by the transmission electron microscope according to Example Embodiments.

### DETAILED DESCRIPTION

Aspects of some embodiments of the present invention will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will more fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

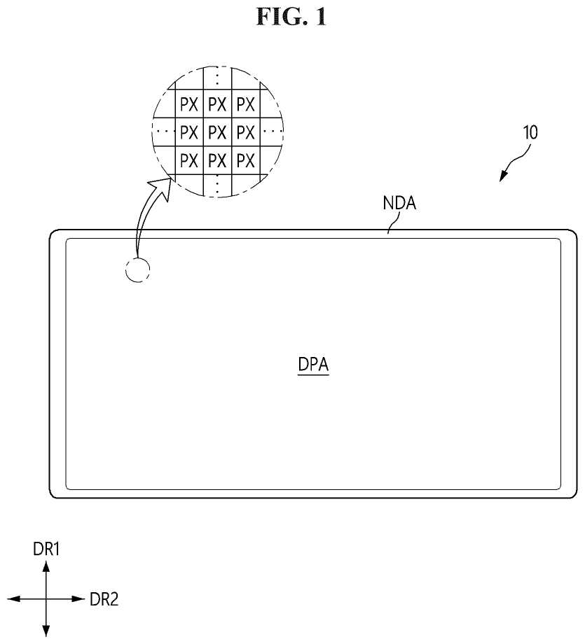

FIG. 1 is a plan view of a display device according to some embodiments of the present disclosure.

Referring to FIG. 1, the display device 10 displays moving images (e.g., video images) and/or still images (e.g., static images). A display device 10 may refer to any electronic device that includes a display screen. For example, the display device 10 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

The display device 10 includes a display panel including a display screen. Examples of the display panel may include an inorganic light-emitting diode display panel, an organic light-emitting display panel, a quantum-dot light-emitting display panel, a plasma display panel, a field emission display panel, etc. In the following description, an inorganic light-emitting diode display panel is employed as an example of the display panel, but embodiments according to the present disclosure are not limited thereto. Any other display panel may be employed as long as the technical idea of the present disclosure can be equally applied.

The shape of the display device 10 may be modified in a variety of ways. For example, the display device 10 may have shapes such as a rectangle with longer lateral sides, a rectangle with longer vertical sides, a square, a quadrangle with rounded corners (vertices), other polygons, a circle, etc. The shape of a display area DPA of the display device 10 may also be similar to the overall shape of the display device 10. In the example shown in FIG. 1, the display device 10 has a rectangular shape with the longer sides in a second direction DR2.

The display device 10 may include a display area DPA and a non-display area NDA. In the display area DPA, images can be displayed. In the non-display area NDA, images are not displayed. According to some embodiments, the non-display area NDA is located in a periphery or outside a footprint of the display area DPA. The display area DPA may be referred to as an active area, while the non-display area NDA may also be referred to as an inactive area. The display area DPA may generally occupy the center of the display device 10.

The display area DPA may include a plurality of pixels PX. The plurality of pixels PX may be arranged in a matrix. The shape of each pixel PX may be, but is not limited to, a rectangle or a square when viewed from the top. Each pixel may have a diamond shape having sides inclined with respect to a direction. The pixels PX may be arranged in stripes or in a pattern of islands. Each of the pixels PX may include one or more light-emitting elements each emitting light of a particular wavelength band to represent a color.

The non-display area NDA may be arranged around the display area DPA. The non-display area NDA may surround the display area DPA entirely or partially. The display area DPA may have a rectangular shape, and the non-display area NDA may be arranged to be adjacent to the four sides of the display area DPA. The non-display area NDA may form the bezel of the display device 10. Lines or circuit drivers included in the display device 10 may be located in each of the non-display area NDA, or external devices may be mounted.

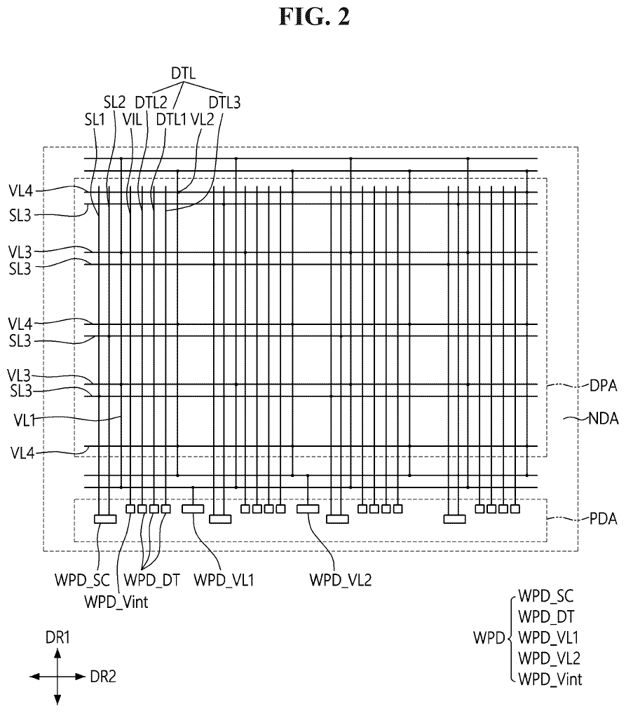

FIG. 2 is a plan view showing arrangement of a plurality of lines included in a display device according to some embodiments of the present disclosure.

Referring to FIG. 2, the display device 10 may include a plurality of lines. The display device 10 may include a plurality of scan lines SL: SL1, SL2 and SL3, a plurality of data lines DTL; DTL1, DTL2 and DTL3, an initialization voltage line VIL, and a plurality of voltage lines VL; VL1, VL2, VL3 and VL4. According to some embodiments, other lines may be further located in the display device 10.

The first scan line SL1 and the second scan line SL2 may be extended in the first direction DR1. The first scan line SL1 and the second scan line SL2 may be located adjacent to each other, and may be spaced apart from other first and second scan lines SL1 and SL2 in the second direction DR2. The first scan line SL1 and the second scan line SL2 may be connected to a scan wire pad WPD_SC connected to a scan driver. The first scan line SL1 and the second scan line SL2 may be extended from a pad area PDA located in the non-display area NDA to the display area DPA.

The third scan line SL3 may be extended in the second direction DR2, and may be spaced apart from another third scan line SL3 in the first direction DR1. One third scan line SL3 may be connected to one or more first scan lines SL1 or one or more second scan lines SL2. According to some embodiments of the present disclosure, the first scan line SL1 and the second scan line SL2 may be formed as a conductive layer that is located on a different layer from the third scan line SL3. The plurality of scan lines SL may have, but is not limited to, a mesh structure on the entire surface of the display area DPA.

As used herein, when an element is referred to as being “connected” or “coupled” to another element, it can be directly connected or coupled to the element or intervening elements may be present. In addition, such elements may be understood as a single integrated element with one portion thereof connected to another portion. Moreover, when an element is referred to as being “connected” to another element, it may be in direct contact with the element and also electrically connected to the element.

The data lines DTL may be extended in the first direction DR1. The data lines DTL may include a first data line DTL1, a second data line DTL2 and a third data line DTL3. The first to third data lines DTL1, DTL2 and DTL3 are located adjacent to one another as a group. The data lines DTL1, DTL2 and DTL3 may be extended from the pad area PDA located in the non-display area NDA to the display area DPA. It should be understood, however, that embodiments according to the present disclosure are not limited thereto. The data lines DTL may be equally spaced apart from one another a first voltage line VL1 and a second voltage line VL2 to be described later.

The initialization voltage line VIL may be extended in the first direction DR1. The initialization voltage line VIL may be located between the data lines DTL and the first and second scan lines SL1 and SL2. The initialization voltage line VIL may be extended from the pad area PDA located in the non-display area NDA to the display area DPA.

The first voltage line VL1 and the second voltage line VL2 may be extended in the first direction DR1, and the third voltage line VL3 and the fourth voltage line VL4 may be extended in the second direction DR2. The first voltage line VL1 and the second voltage line VL2 may be arranged alternately in the second direction DR2, and the third voltage line VL3 and the fourth voltage line VL4 may be arranged alternately in the first direction DR1. The first voltage lines VL1 and the second voltage lines VL2 may be extended in the first direction DR1 and may traverse the display area DPA. Some of the third voltage line VL3 and the fourth voltage lines VL4 may be located in the display area DPA while the others may be located in the non-display area NDA located on the both sides of the display area DPA in the first direction DR1. The first voltage lines VL1 and the second voltage lines VL2 may be formed as a conductive layer located on a different layer from the third voltage lines VL3 and the fourth voltage lines VL4. The first voltage line VL1 may be connected to at least one third voltage line VL3, and the second voltage line VL2 may be connected to at least one fourth voltage line VL4, such that the plurality of voltage lines VL may have a mesh structure in the entirely display are DPA. It is, however, to be understood that embodiments according to the present disclosure are not limited thereto.

The first scan lines SL1, the second scan lines SL2, the data lines DTL, the initialization voltage line VIL, the first voltage lines VL1 and the second voltage lines VL2 may be electrically connected to one or more wire pads WPD. The wire pads WPD may be located in the non-display areas NDA. According to some embodiments of the present disclosure, the wire pads WPD may be located in the pad area PDA located on the lower side of the display area DPA that is the opposite in the first direction DR1. The first and second scan lines SL1 and SL2 may be connected to the scan wire pad WPD_SC located in the pad area PDA, and the data lines DTL may be connected to different data wire pads WPD_DT, respectively. The initialization voltage line VIL may be connected to the initialization wiring pad WPD_Vint, the first voltage line VL1 may be connected to a first voltage wire pad WPD_VL1, and the second voltage line VL2 may be connected to the second voltage wire pad WPD_VL2. External devices may be mounted on the wire pads WPD. External devices may be mounted on the wire pads WPD by an anisotropic conductive film, ultrasonic bonding, etc. Although the wire pads WPD are located in the pad area PDA located on the lower side of the display area DPA in the drawings, embodiments according to the present disclosure are not limited thereto. Some of the plurality of wire pads WPD may be located on the upper side or on one of the left and right sides of the display area DPA.

Each of the pixels PX or sub-pixels SPXn of the display device 10 includes a pixel driving circuit, where n is an integer of 1 to 3. The above-described lines may pass through each of the pixels PX or the periphery thereof to apply a driving signal to the pixel driving circuit. The pixel driving circuit may include transistors and a capacitor. The numbers of transistors and capacitors of each pixel driving circuit may be changed in a variety of ways. According to some embodiments of the present disclosure, each of the sub-pixels SPXn of the display device 10 may have a 3T1C structure, i.e., a pixel driving circuit includes three transistors and one capacitor. In the following description, the pixel driving circuit having the 3T1C structure will be described as an example. It is, however, to be understood that embodiments according to the present disclosure are not limited thereto. A variety of modified structure may be employed such as a 2T1C structure, a 7T1C structure and a 6T1C structure.

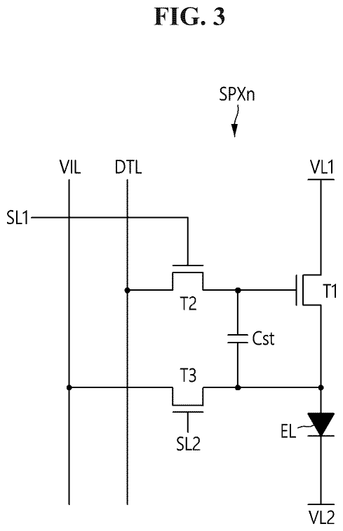

FIG. 3 is an equivalent circuit diagram of a sub-pixel according to some embodiments of the present disclosure.

Referring to FIG. 3, each of the sub-pixels SPXn of the display device 10 according to some embodiments includes three transistors T1, T2 and T3 and one storage capacitor Cst in addition to a light-emitting diode EL.

The light-emitting diode EL emits light in proportional to the current supplied through the first transistor T1. The light-emitting diode EL includes a first electrode, a second electrode, and at least one light-emitting element located therebetween. The light-emitting element may emit light in a particular wavelength range by an electric signal transmitted from the first electrode and the second electrode.

A first end of the light-emitting diode EL may be connected to a source electrode of the first transistor T1, and a second end thereof may be connected to a second voltage line VL2 from which a low-level voltage (hereinafter referred to as a second supply voltage) lower than a high-level voltage (hereinafter referred to as a first supply voltage) of a first voltage line VL1 is applied.

The first transistor T1 adjusts a current flowing from the first voltage line VL1 from which the first supply voltage is supplied to the light-emitting diode EL according to the voltage difference between a gate electrode and the source electrode. For example, the first transistor T1 may be a driving transistor for driving the light-emitting diode EL. The gate electrode of the first transistor T1 may be connected to a source electrode of the second transistor T2, the source electrode thereof may be connected to the first electrode of the light-emitting diode EL, and the drain electrode thereof may be connected to the first voltage line VL1 from which the first supply voltage is applied.

The second transistor T2 is turned on by a scan signal of the first scan line SL1 to connect the data line DTL with the gate electrode of the first transistor T1. The gate electrode of the second transistor T2 may be connected to the first scan line SL1, the source electrode thereof may be connected to the gate electrode of the first transistor T1, and the drain electrode thereof may be connected to the data line DTL.

A third transistor T3 may be turned on by a scan signal of a second scan line SL2 to connect the initialization voltage line VIL with the first end of the light-emitting diode EL. The gate electrode of the third transistor T3 may be connected to the second scan line SL2, the drain electrode thereof may be connected to the initialization voltage line VIL, and the source electrode thereof may be connected to one end of the light-emitting diode EL or the source electrode of the first transistor T1.

The source electrode and the drain electrode of each of the transistors T1, T2 and T3 are not limited to those described above. They may be connected in the opposite way. In addition, each of the transistors T1, T2 and T3 may be formed as a thin-film transistor. In addition, although each of the transistors T1, T2 and T3 implemented as an n-type MOSFET (metal oxide semiconductor field effect transistor) in the example shown in FIG. 3, embodiments according to the present disclosure are not limited thereto. That is to say, each of the transistors T1, T2 and T3 may be implemented as a p-type MOSFET, or some of the transistors T1, T2 and T3 may be implemented as n-type MOSFETs while the others may be implemented as p-type MOSFETs.

The storage capacitor Cst is formed between the gate electrode and the source electrode of the first transistor T1. The storage capacitor Cst stores a voltage difference between the gate voltage and the source voltage of the first transistor T1.

Hereinafter, the structure of one pixel PX of the display device 10 according to some embodiments will be described in more detail with reference to other drawings.

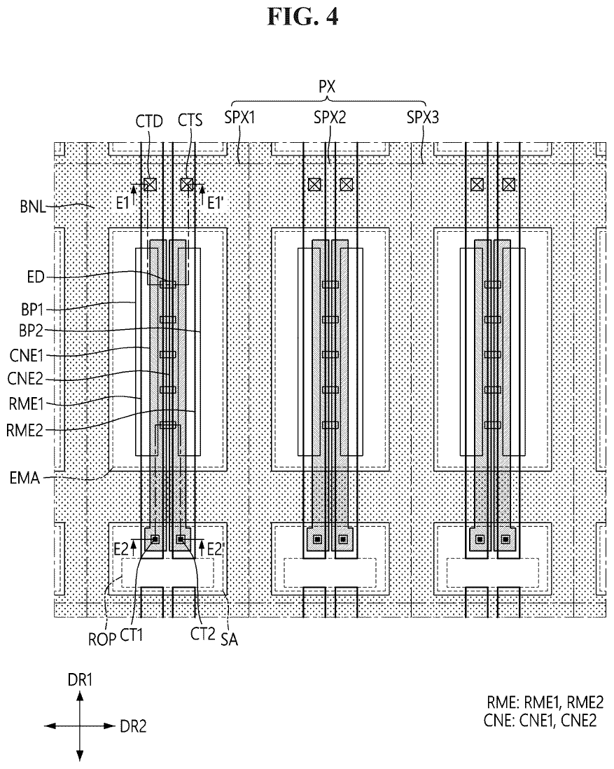

FIG. 4 is a plan view showing a pixel of a display device according to some embodiments of the present disclosure. FIG. 4 shows a layout of electrodes RME; RME1 and RME2, bank patterns BP1 and BP2, a bank layer BNL, light-emitting elements ED, and connection electrodes CNE: CNE1 and CNE2 located in a pixel PX of a display device 10 when viewed from the top.

Referring to FIG. 4, each of the pixels PX of the display device 10 may include a plurality of sub-pixels SPXn. For example, a pixel PX may include a first sub-pixel SPX1, a second sub-pixel SPX2 and a third sub-pixel SPX3. The first sub-pixel SPX1 may emit light of a first color, the second sub-pixel SPX2 may emit light of a second color, and the third sub-pixel SPX3 may emit light of a third color. For example, the first color may be blue, the second color may be green, and the third color may be red. It is, however, to be understood that embodiments according to the present disclosure are not limited thereto. All the sub-pixels SPXn may emit light of the same color. According to some embodiments of the present disclosure, the sub-pixels SPXn may emit blue light. Although the single pixel PX includes three sub-pixels SPXn in the example shown in the drawings, embodiments according to the present disclosure are not limited thereto. The pixel PX may include more than three sub-pixels SPXn.

Each of the sub-pixels SPXn of the display device 10 may include an emission area EMA and a non-emission area. In the emission area EMA, light-emitting elements ED are arranged to emit light of a particular wavelength band. In the non-emission area, the light-emitting elements ED are not located and the lights emitted from the light-emitting elements ED do not reach, and thus no light exits therefrom.

The emission area EMA may include an area in which the light-emitting elements ED are located, and may include an area adjacent to the light-emitting elements ED where lights emitted from the light-emitting elements ED exit. For example, the emission area EMA may also include an area in which lights emitted from the light-emitting elements ED are reflected or refracted by other elements to exit. The plurality of light-emitting elements ED may be located in each of the sub-pixels SPXn, and the emission area may include the area where the light-emitting elements are located and the adjacent area.

Although the emission areas EMA of the sub-pixels SPXn have the uniform area in the example shown in the drawings, embodiments according to the present disclosure are not limited thereto. In some embodiments, the emission areas EMA of the sub-pixels SPXn may have different areas depending on a color or wavelength band of light emitted from the light-emitting elements ED located in the respective sub-pixels.

Each of the sub-pixels SPXn may further include a subsidiary area SA located in the non-emission area. The subsidiary area SA of each sub-pixel SPXn may be located on the lower side of the emission area EMA that is the opposite side in the first direction DR1. The emission areas EMA and the subsidiary areas SA may be arranged alternately in the first direction DR1, and each subsidiary area SA may be located between the emission areas EMA of different sub-pixels SPXn spaced apart from each other in the first direction DR1. For example, the emission areas EMA and the subsidiary areas SA may be alternately arranged in the first direction DR1, and the emission areas EMA and the subsidiary areas SA may be repeatedly arranged in the second direction DR2. It is, however, to be understood that embodiments according to the present disclosure are not limited thereto. The emission areas EMA and the subsidiary areas SA of the plurality of pixels PX may have an arrangement different from that of FIG. 4.

No light-emitting diode ED is located in the subsidiary areas SA and thus no light exits therefrom. The electrodes RME located in the sub-pixels SPXn may be partially arranged in the subsidiary areas SA. The electrodes RME located in different sub-pixels SPXn may be arranged separately from one another at separation regions ROP of the subsidiary areas SA.

The lines and circuit elements of the circuit layer located in each pixel PX and connected to the light-emitting elements ED may be connected to the first to third sub-pixels SPX1, SPX2 and SPX3. It should be noted that the lines and circuit elements may not be located in the area occupied by each sub-pixel SPXn or the emission area EMA but may be arranged regardless of the location of the emission area EMA in one pixel PX.

The bank layer BNL may be arranged to surround the plurality of sub-pixels SPXn, the emission area EMA and the subsidiary area SA. The bank layer BNL may be located at the boundary between the sub-pixels SPXn adjacent to each other in the first direction DR1 and the second direction DR2, and may also be located at the boundary between the emission area EMA and the subsidiary area SA. The sub-pixels SPXn, the emission areas EMA and the subsidiary areas SA of the display device 10 may be distinguished from one another by the bank layer BNL. The distance between the plurality of sub-pixels SPXn, the emission areas EMA and the subsidiary areas SA may vary depending on the width of the bank layer BNL.

The bank layer BNL may be arranged in a lattice pattern on the front surface of the display area DPA including portions extended in the first direction DR1 and the second direction DR2 when viewed from the top. The bank layer BNL may be arranged along the border of each of the sub-pixels PXn to distinguish between adjacent sub-pixels PXn. In addition, the bank layer BNL may be arranged to surround the emission area EMA and the subsidiary area SA located in each of the sub-pixels SPXn to distinguish between them.

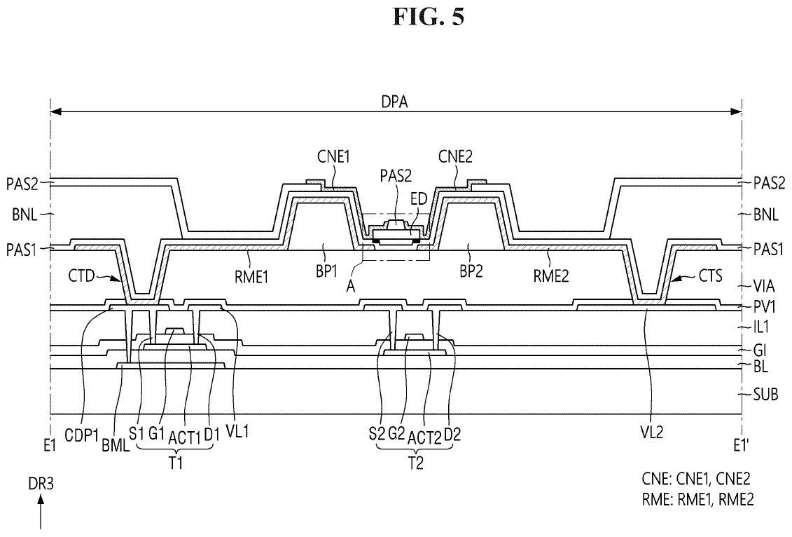

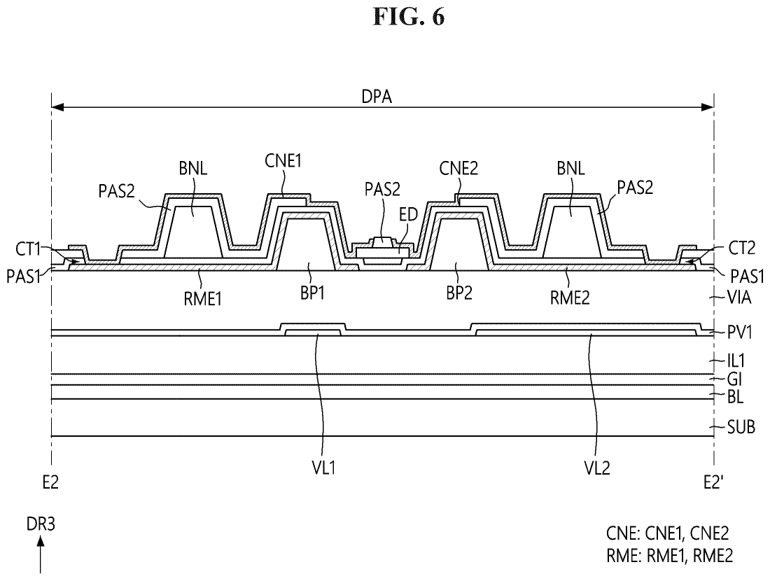

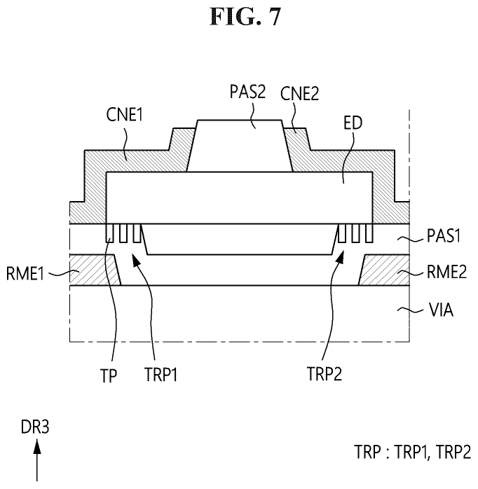

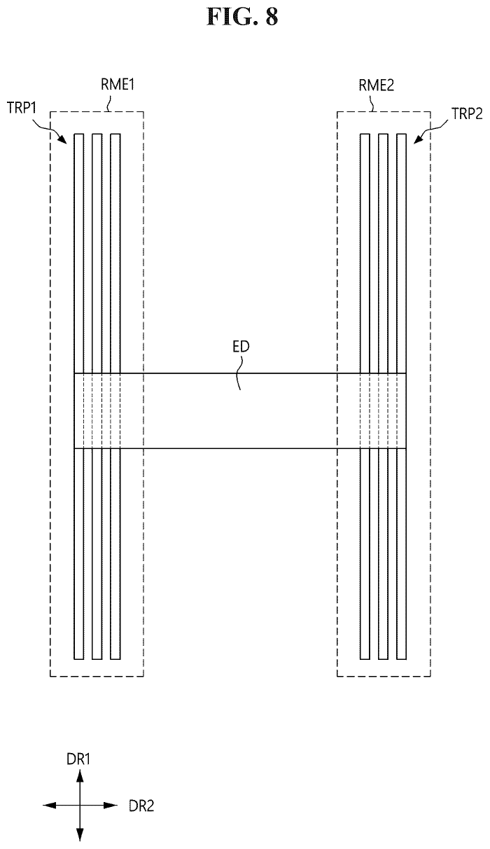

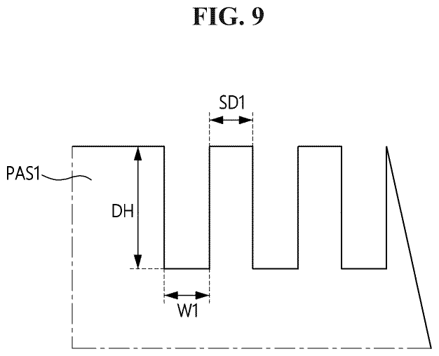

FIG. 5 is a cross-sectional view taken along line E1-E1′ of FIG. 4. FIG. 6 is a cross-sectional view taken along line E2-E2′ of FIG. 4. FIG. 7 is an enlarged view of area A shown in FIG. 5. FIG. 8 is a plan view showing area A of FIG. 5. FIG. 9 is a cross-sectional view showing a first insulating layer of a display device according to some embodiments.

FIG. 5 shows a cross section passing through the both ends of the light-emitting elements ED located in the first sub-pixel SPX1 and electrode contact holes CTD and CTS; and FIG. 6 shows a cross section passing through the both ends of the light-emitting elements ED located in the first sub-pixel SPXn and contacts CT1 and CT2. FIG. 7 shows a via layer VIA, electrodes RME1 and RME2, a first insulating layer PAS1, a light-emitting element ED, and connection electrodes CNE1 and CNE2. FIG. 8 shows the electrodes RME1 and RME2, trench portions TRP, and the light-emitting element ED. FIG. 9 shows the trench portions TRP of the first insulating layer PAS1.

Referring to FIGS. 5 to 9 in conjunction with FIG. 4, the display device 10 may include a first substrate SUB, and a semiconductor layer, a plurality of conductive layers and a plurality of insulating layers arranged thereon. In addition, the display device 10 may include a plurality of electrodes RME: RME1 and RME2, light-emitting elements ED, and connection electrodes CNE; CNE1 and CNE2 located on the first substrate SUB. The semiconductor layer, the conductive layers and the insulating layers may form a circuit layer of the display device 10.

The first substrate SUB may be an insulating substrate. The first substrate SUB may be made of an insulating material such as glass, quartz and a polymer resin. The first substrate SUB may be either a rigid substrate or a flexible substrate that can be bent, folded, or rolled. The first substrate SUB may include the display area DPA and the non-display area NDA surrounding the display area DPA. The display area DPA may include the emission area EMA and the subsidiary area SA which is a portion of the non-emission area.

A first conductive layer may be located on the first substrate SUB. The first conductive layer includes a bottom metal layer BML. The bottom metal layer BML is arranged to overlap an active layer ACT1 of a first transistor T1. The bottom metal layer BML may prevent or reduce instances of light being incident on the first active layer ACT1 of the first transistor or may be electrically connected to the first active layer ACT1 to stabilize the electrical characteristics of the first transistor T1. It is to be noted that the bottom metal layer BML may be eliminated.

A buffer layer BL may be located on the bottom metal layer BML and the first substrate SUB. The buffer layer BL may be formed on the first substrate SUB to protect the transistors of the pixel PX from moisture permeating through the first substrate SUB that is susceptible to moisture permeation, and may also provide a flat surface.

The semiconductor layer is located on the buffer layer BL. The semiconductor layer may include the first active layer ACT1 of the first transistor T1 and the second active layer ACT2 of the second transistor T2. The first active layer ACT1 and the second active layer ACT2 may be arranged to partially overlap the first gate electrode G1 and the second gate electrode G2 of a second conductive layer, respectively, which will be described later.

The semiconductor layer may include polycrystalline silicon, monocrystalline silicon, an oxide semiconductor, etc. In other embodiments, the semiconductor layer may include polycrystalline silicon. The oxide semiconductor may be an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), indium-gallium zinc tin oxide (IGZTO), etc.

Although only one first transistor T1 is located in the sub-pixel SPXn of the display device 10 in the drawing, embodiments according to the present disclosure are not limited thereto. A larger number of transistors may be included in the display device 10.

A first gate insulator GI is located on the semiconductor layer and the buffer layer BL in the display area DPA. The first gate insulator GI may not be located in the pad area PDA. It may work as a gate insulating film of each of the transistors T1 and T2. Although the first gate insulator GI is arranged entirely on the buffer layer BL in the example shown in the drawings, embodiments according to the present disclosure are not limited thereto. In some embodiments, the first gate insulator GI is patterned together with the gate electrodes G1 and G2 of the second conductive layer to be described later, and is partially arranged between the second conductive layer and the active layers ACT1 and ACT2 of the semiconductor layer.

The second conductive layer is located on the first gate insulator GI. The second conductive layer may include a first gate electrode G1 of the first transistor T1, and a second gate electrode G2 of the second transistor T2. The first gate electrode G1 may overlap a channel region of the first active layer ACT1 in the third direction DR3, which is the thickness direction. The second gate electrode G2 may overlap a channel region of the second active layer ACT2 in the third direction DR3, which is the thickness direction. According to some embodiments, the second conductive layer may further include an electrode of a storage capacitor.

A first interlayer dielectric layer IL1 is located on the second conductive layer. The first interlayer dielectric layer IL1 may work as an insulating film between the second conductive layer and other layers located thereon and can protect the second conductive layer.

The third conductive layer is located on the first interlayer dielectric layer IL1. The third conductive layer may include the first voltage line VL1 and the second voltage line VL2 located in the display area DPA, a first conductive pattern CDP1, and the source electrodes S1 and S2 and drain electrodes D1 and D2 of the transistors T1 and T2. According to some embodiments, the third conductive layer may further include the other electrode of the storage capacitor.

A high-level voltage (or a first supply voltage) may be applied to the first voltage line VL1 to be transmitted to the first electrode RME1, and a low-level voltage (or a second supply voltage) may be applied to the second voltage line VL2 to be transmitted to the second electrode RME2. A portion of the first voltage line VL1 may be in contact with the first active layer ACT1 of the first transistor T1 through a contact hole penetrating the first interlayer dielectric layer IL1 and the first gate insulator GI. The first voltage line VL1 may work as the first drain electrode D1 of the first transistor T1. The second voltage line VL2 may be directly connected to the second electrode RME2 to be described later.

The first conductive pattern CDP1 may be in contact with the first active layer ACT1 of the first transistor T1 through a contact hole penetrating the first interlayer dielectric layer IL1 and the first gate insulator GI. The first conductive pattern CDP1 may be in contact with the bottom metal layer BML through another contact hole. The first conductive pattern CD1 may work as a first source electrode S1 of the first transistor T1. In addition, the first conductive pattern CDP1 may be connected to a first electrode RME1 or a first connection electrode CNE1 to be described later. The first transistor T1 may transfer the first supply voltage applied from the first voltage line VL1 to the first electrode RME1 or the first connection electrode CNE1.

The second source electrode S2 and the second drain electrode D2 may be in contact with the second active layer ACT2 of the second transistor T2 through contact holes penetrating the first interlayer dielectric layer IL1 and the first gate insulator GI, respectively. The second transistor T2 may be one of the switching transistors described above with reference to FIG. 3. The second transistor T2 may transmit a signal applied from the data line DTL of FIG. 3 to the first transistor T1 or may transmit a signal applied from the initialization voltage line VIL of FIG. 3 to the other electrode of the storage capacitor.

A first passivation layer PV1 is arranged over the third conductive layer. The first passivation layer PV1 may work as an insulating film between the third conductive layer and other layers and can protect the third conductive layer.

The buffer layer BL, the first gate insulating layer GI, the first interlayer dielectric layer IL1 and the first passivation layer PV1 may be made up of multiple inorganic layers stacked on one another alternately. For example, the buffer layer BL, the first gate insulating layer GI, the first interlayer dielectric layer IL1 and the first passivation layer PV1 may be made up of a double layer in which inorganic layers including at least one of silicon oxide (SiOx), silicon nitride (SiNx) or silicon oxynitride (SiON) are stacked on one another or multiple layers in which they are alternately stacked on one another. It is, however, to be understood that embodiments according to the present disclosure are not limited thereto. The buffer layer BL, the first gate insulating layer GI, the first interlayer dielectric layer IL1 and the first passivation layer PV1 may be made up of a single inorganic layer including the above-described insulating material. In addition, in some embodiments, the first interlayer dielectric layer IL1 may be made of an organic insulating material such as polyimide (PI).

A via layer VIA is located on the third conductive layer in the display area DPA. The via layer VIA may include an organic insulating material, e.g., an organic insulating material such as polyimide (PI), to provide a flat surface over the underlying conductive layers having different heights. It should be noted that the via layer VIA may be eliminated in some implementations.

The display device 10 may include the bank patterns BP1 and BP2, a plurality of electrodes RME: RME1 and RME2, the bank layer BNL, the light-emitting elements ED, and the connection electrodes CNE: CNE1 and CNE2, as a display element layer located on the via layer VIA. In addition, the display device 10 may include a plurality of insulating layers PAS1, PAS2 and PAS3 located on the via layer VIA.

The bank patterns BP1 and BP2 may be located in the emission area EMA of each sub-pixel SPX. Each of the bank patterns BP1 and BP2 may have a shape that has a constant width in the second direction DR2 and is extended in the first direction DR1.

For example, the bank patterns BP1 and BP2 may include a first bank pattern BP1 and a second bank pattern BP2 spaced apart from each other in the second direction DR2 in the emission area EMA of each sub-pixel SPXn. The first bank pattern BP1 may be located on the left side of the center of the emission area EMA that is one side in the second direction DR2, and the second bank pattern BP2 may be spaced apart from the first bank pattern BP1 and may be located on the right side of the center of the emission area EMA that is the opposite side in the second direction DR2. The first bank pattern BP1 and the second bank pattern BP2 may be alternately arranged along the second direction DR2 and may be arranged in an island-like pattern in the display area DPA. The plurality of light-emitting elements ED may be located between the first bank pattern BP1 and the second bank pattern BP2.

The length of the first bank pattern BP1 may be equal to the length of the second bank pattern BP2 in the first direction DR1. The lengths of the first bank pattern BP1 and the second bank pattern BP2 may be smaller than the length of the emission area EMA surrounded by the bank layer BNL in the first direction DR1. The first bank pattern BP1 and the second bank pattern BP2 may be spaced apart from a portion of the bank layer BNL that is extended in the second direction DR2. It should be understood, however, that embodiments according to the present disclosure are not limited thereto. The bank patterns BP1 and BP2 may be integrated with the bank layer BNL or may partially overlap with a portion of the bank layer BNL that is extended in the second direction DR2. In this instance, the lengths of the bank patterns BP1 and BP2 in the first direction DR1 may be equal to or greater than the length of the emission area EMA surrounded by the bank layer BNL in the first direction DR1.

The first bank pattern BP1 and the second bank pattern BP2 may have the same width in the second direction DR2. It should be understood, however, that embodiments according to the present disclosure are not limited thereto. They may have different widths. For example, one of the bank patterns may have a greater width than the other one, and the larger bank pattern may be arranged across the emission areas EMA of different sub-pixels SPXn adjacent to each other in the second direction DR2. In this instance, when the bank patterns are arranged across the emission areas EMA, portions of the bank layer BNL extended in the first direction DR1 may overlap the second bank pattern BP2 in the thickness direction. Although two bank patterns BP1 and BP2 are located in each sub-pixel SPXn and have to have the same width in the example shown in the drawings, embodiments according to the present disclosure are not limited thereto. The number and shape of the bank patterns BP1 and BP2 may vary depending on the number or arrangement structure of the electrodes RME.

The plurality of bank patterns BP1 and BP2 may be located on the via layer VIA. For example, the bank patterns BP1 and BP2 may be arranged directly on the via layer VIA, and may have a structure that at least partly protrudes from the upper surface of the via layer VIA. The protruding portions of the bank patterns BP1 BP2 may have inclined or bent side surfaces. The lights emitted from the light-emitting elements ED may be reflected by the electrodes RME located on the bank patterns BP1 and BP2 so that the lights may exit toward the upper side of the via layer VIA. Unlike that shown in the drawings, the bank patterns BP1 and BP2 may have a semi-circular or semi-elliptical shape with a curved outer surface in the cross-sectional view. The bank patterns BP1 and BP2 may include, but is not limited to, an organic insulating material such as polyimide (PI).

The plurality of electrodes RME; RME1 and RME2 have a shape extended in one direction and are located in each of the sub-pixels SPXn. The plurality of electrodes RME1 and RME2 may be extended in the first direction DR1 to be located in the emission area EMA and the subsidiary area SA of the sub-pixel SPXn, and they may be spaced apart from one another in the second direction DR2. The plurality of electrodes RME may be electrically connected to the light-emitting elements ED, which will be described later. It should be understood, however, that they may not be electrically connected to the light-emitting elements ED.

The display device 10 may include a first electrode RME1 and a second electrode RME2 located in each of the sub-pixels SPXn. The first electrode RME1 is located on the left side of the center of the emission area EMA, and the second electrode RME2 is spaced apart from the first electrode RME1 in the second direction DR2 and is located on the right side of the center of the emission area EMA. The first electrode RME1 may be located on the first bank pattern BP1, and the second electrode RME2 may be located on the second bank pattern BP2. The first electrode RME1 and the second electrode RME2 may be extended beyond the bank layer BNL and may be partially arranged in the sub-pixel SPXn and the subsidiary area SA. The first electrode RME1 and the second electrode RME2 of a sub-pixel SPXn may be spaced apart from those of another sub-pixel SPXn at the separation region ROP located in the subsidiary area SA of one of the sub-pixels SPXn.

Although two electrodes RME are located in each sub-pixel SPXn and have a shape extended in the first direction DR1 in the drawings, but embodiments according to the present disclosure are not limited thereto. The electrodes RME may be arranged, or the electrodes RME may be partially bent, and may have shapes having different widths at different positions.

The first electrode RME1 and the second electrode RME2 may be located on at least inclined side surfaces of the bank patterns BP1 and BP2. According to some embodiments of the present disclosure, the width of the plurality of electrodes RME measured in the second direction DR2 may be smaller than the width of the bank patterns BP1 and BP2 measured in the second direction DR2. The distance between the first electrode RME1 and the second electrode RME2 spaced apart from each other in the second direction DR2 may be smaller than the distance between the bank patterns BP1 and BP2. At least a portion of the first electrode RME1 and the second electrode RME2 may be arranged directly on the via layer VIA, so that they may be arranged on the same plane.

The light-emitting elements ED located between the bank patterns BP1 and BP2 may emit lights through the both ends. The emitted lights may be directed to the electrodes RME located on the bank patterns BP1 and BP2. The portion of each of the electrodes RME that is located on the bank patterns BP1 and BP2 may reflect lights emitted from the light-emitting elements ED. The first electrodes RME1 and the second electrodes RME2 may be arranged to cover the side surfaces of the bank patterns BP1 and BP2 on at least one side to reflect lights emitted from the light-emitting elements ED.

Each of the electrodes RME may be in direct contact with the third conductive layer through the electrode contact holes CTD and CTS where it overlaps with the bank layer BNL between the emission area EMA and the subsidiary area SA. The first electrode contact hole CTD may be formed where the bank layer BNL and the first electrode RME1 overlap each other. The second electrode contact hole CTS may be formed where the bank layer BNL and the second electrode RME2 overlap each other. The first electrode RME1 may be in contact with the first conductive pattern CDP1 through the first electrode contact hole CTD penetrating through the via layer VIA and the first passivation layer PV1. The second electrode RME2 may be in contact with the second voltage line VL2 through the second electrode contact hole CTS penetrating through the via layer VIA and the first passivation layer PV1. The first electrode RME1 may be electrically connected to the first transistor T1 through the first conductive pattern CDP1 to receive the first supply voltage. The second electrode 22 may be electrically connected to the second voltage line VL2 to receive the second supply voltage. It is, however, to be understood that embodiments according to the present disclosure are not limited thereto. According to some embodiments, each of the electrodes RME1 and RME2 may not be electrically connected to the voltage lines VL1 and VL2 of the third conductive layer and connection electrodes CNE to be described later may be directly connected to the third conductive layer.

Each of the electrodes RME may include a conductive material having a high reflectance. For example, the electrodes RME may include a metal such as silver (Ag), copper (Cu) and aluminum (AI), or may include an alloy including aluminum (AI), nickel (Ni), lanthanum (La), or the like, or a stack of a metal layer such as titanium (Ti), molybdenum (Mo) and niobium (Nb) and the alloy. In some embodiments, the electrodes RME may be made up of a double- or multi-layer in which an alloy containing aluminum (AI) and at least one metal layer made of titanium (Ti), molybdenum (Mo) and niobium (Nb) are stacked on one another.

It is, however, to be understood that embodiments according to the present disclosure are not limited thereto. The electrodes RME may further include a transparent conductive material. For example, each of the electrodes RME may include a material such as ITO, IZO and ITZO. In some embodiments, each of the electrodes RME1 and RME2 may have a structure in which one or more layers of a transparent conductive material and one or more metal layers having high reflectivity are stacked on one another, or may be made up of a single layer including them. For example, each of the electrodes RME may have a stack structure such as ITO/Ag/ITO/, ITO/Ag/IZO, or ITO/Ag/ITZO/IZO. The electrodes RME may be electrically connected to the light-emitting elements ED and may reflect some of the lights emitted from the light-emitting elements ED toward the upper side of the first substrate SUB.

The first insulating layer PAS1 may be located on the front surface of the display area DPA, and may be located on the via layer VIA and the plurality of electrodes RME. The first insulating layer PAS1 can protect the plurality of electrodes RME and can insulate different electrodes RME from each other. As the first insulating layer PAS1 is arranged to cover the electrodes RME before the bank layer BNL is formed, it may be possible to prevent or reduce damage to the electrode RME during the process of forming the bank layer BNL. In addition, the first insulating layer PAS1 may also prevent or reduce damage to the light-emitting elements ED located thereon that are brought into contact with other elements.

According to some embodiments, the first insulating layer PAS1 may have a step so that a portion of the upper surface is recessed between the electrodes RME spaced apart from one another in the second direction DR2. The light-emitting elements ED may be located on the upper surface of the step of the first insulating layer PAS1, and a space may be formed between the light-emitting elements ED and the first insulating layer PAS1.

As described above, the first insulating layer PAS1 may cover the electrodes RME to insulate and protect the electrodes RME. A seam may occur on the side surfaces of the first insulating layer PAS1 due to a taper angle on the side surfaces of the underlying electrodes RME, a double taper shape, or a reverse taper shape. As used herein, a seam may be a crack in the first insulating layer PAS1. If there is a seam in the first insulating layer PAS1, an etchant or moisture during a subsequent process permeates through the seam, damaging the electrodes RME.

According to some embodiments, the first insulating layer PAS1 includes silicon oxynitride (SiON) to prevent or reduce seams, thereby preventing or reducing damage to the electrodes RME.

The material of the first insulating layer PAS1 should satisfy a number of conditions. The above conditions are: 1) the material should be a material that can be deposited at a temperature of 200° C. or lower; 2) the material must have excellent step coverage to prevent or reduce seams; 3) the material should be easily etched together with the second insulating layer PAS2; and 4) the material should have a thickness of 3,000 Å or less to facilitate the formation of an electric field during the process of aligning light-emitting elements ED.

According to some embodiments, the first insulating layer PAS1 may include silicon oxynitride (SiON) that satisfies the above-described conditions. A film made of silicon oxynitride can be formed at a low temperature of 200° C. or lower.

The above-described silicon oxynitride contained in the first insulating layer PAS1 may be represented by Chemical Formula 1 below:

SixOyNz Chemical Formula 1

where x, y and z satisfy 34.6<x<42.9, 24.2<y<63.8 and 1.5<z<32.9, respectively, and x, y and z denote atomic ratios.

Silicon oxynitride may be composed of Si, O and N with the atomic ratios in the above-mentioned range. Specifically, the atomic percent of Si may be greater than 34.6 at % and less than 42.9 at %, the atomic percent of O may be greater than 24.2 at % and less than 63.8 at %, and the atomic percent of N may be greater than 1.5 at % and less than 32.9 at %.

In order for the first insulating layer PAS1 to have excellent step coverage, it is advantageous to have a low sticking coefficient. According to some embodiments, the first insulating layer PAS1 may contain greater than 1.5 at % of N so as to lower the sticking coefficient, and may contain less than 32.9 at % of N so as to prevent or reduce an increase in dielectric constant. The first insulating layer PAS1 includes N to improve step coverage, thereby preventing or reducing a failure or a seam on the side surfaces of the electrodes RME.

In addition, the first insulating layer PAS1 may have an etch selectivity of 4.1 or more with respect to the second insulating layer PAS2. For example, silicon oxynitride may have an etch selectivity of 4.1 or more with respect to silicon nitride (SiNx). The connection electrodes CNE may be connected to the electrodes RME1 and RME2 through the contacts CT1 and CT2 penetrating the first and second insulating layers PAS1 and PAS2. In this instance, the contacts CT1 and CT2 may be formed by simultaneously dry etching the first insulating layer PAS1 and the second insulating layer PAS2. According to some embodiments, the first insulating layer PAS1 containing silicon oxynitride has an etch selectivity of 4.1 or more with the second insulating layer PAS2 containing silicon nitride, so that it is easy to form the contacts CT1 and CT2.

In addition, the first insulating layer PAS1 may have a thickness of 2,000 Å to 3,000 Å. The light-emitting element ED may be aligned by an electric field formed over the first insulating layer PAS1 through the electrodes RME. According to some embodiments, the thickness of the first insulating layer PAS1 containing silicon oxynitride is equal to or greater than 2,000 Å so as to prevent or reduce a seam on the side surfaces of the electrodes RME. In addition, by forming the first insulating layer PAS1 to have a thickness equal to or less than 3,000 Å, it may be possible to prevent or reduce increases in the dielectric constant of the first insulating layer PAS1, thereby forming an electric field to easily align the light-emitting element ED.

In addition, the first insulating layer PAS1 may have a refractive index (e.g., a set or predetermined refractive index) so that light emitted from the light-emitting element ED is reflected off the electrodes RME to exit. For example, the first insulating layer PAS1 may have a refractive index greater than 1.4 and less than 1.63. In this instance, the wavelength of light may be 633 nm. As described above, the first insulating layer PAS1 contains O and N. As the atomic ratio of N increases, the refractive index may increase, while as the atomic ratio of O increases, the refractive index may decrease. The first insulating layer PAS1 is composed of the atomic ratios of O and N in the above-described range, and has a refractive index greater than 1.4 and less than 1.63, thereby relatively improving the efficiency of light output from the light-emitting element ED.

As described above, the first insulating layer PAS1 according to some embodiments contains silicon oxynitride having the composition ratio of Chemical Formula 1 above, so that it may be possible to prevent or reduce a seam on the side surfaces of the electrodes RME, to facilitate alignment of the light-emitting elements ED, and to relatively improve the emission efficiency.

Incidentally, the first insulating layer PAS1 may include a plurality of trench portions TRP so as to relatively improve alignment of the light-emitting elements ED.

Referring to FIGS. 7 to 9, the first insulating layer PAS1 may include the trench portions TRP. The trench portions TRP may be grooves concave from the surface of the first insulating layer PAS1 toward the via layer VIA. The trench portions TRP may be formed as one body with the first insulating layer PAS1 and may be a portion of the first insulating layer PAS1. The trench portions TRP may be located under the light-emitting element ED when viewed from the top and can relatively improve adhesion of the light-emitting element ED by inducing physical surface friction with the light-emitting element ED.

The trench portions TRP may include a first trench portion TRP1 and a second trench portion TRP2. The first trench portion TRP1 may overlap with the first electrode RME1 and may be extended in parallel with it, and may overlap with one end of the light-emitting element ED. The second trench portion TRP2 may overlap with the second electrode RME2 and may be extended in parallel with it, and may overlap with the opposite end of the light-emitting element ED. The first trench portion TRP1 and the second trench portion TRP2 may be extended in the first direction DR1 and may be spaced apart from each other in the second direction DR2. The first trench portion TRP1 and the second trench portion TRP2 may be arranged parallel to each other.

Each of the first trench portion TRP1 and the second trench portion TRP2 may be in contact with the light-emitting element ED. For example, the first trench portion TRP1 may be in contact with the lower surface of one end of the light-emitting element ED, and the second trench portion TRP2 may be in contact with the lower surface of the other end of the light-emitting element ED. The first trench portion TRP1 and the second trench portion TRP2 may be located within the length of the light-emitting element ED where they overlap with the light-emitting element ED. For example, the width of the first trench portion TRP1 in the second direction DR2 may be smaller than the length of the light-emitting element ED. Likewise, the width of the second trench portion TRP2 in the second direction DR2 may be smaller than the length of the light-emitting element ED. The sum of the width of the first trench portion TRP1 and the width of the second trench portion TRP2 may be smaller than the length of the light-emitting element ED.

In addition, the side of the first trench portion TRP1 and the side of one end of the light-emitting element ED may be aligned with each other. If the first trench portion TRP1 is located more to the outside than the side of one end of the light-emitting element ED, the light reflected off the electrodes RME is reflected and diffused in the trenches TP of the first trench portion TRP1, reducing the emission efficiency.

Each of the first trench portion TRP1 and the second trench portion TRP2 may include a plurality of trenches TP. The plurality of trenches TP may be extended in the first direction DR1 and may be spaced apart from each other in the second direction DR2. The trenches TP may have a depth DH of 1 to 30% of the thickness of the first insulating layer PAS1. The trenches TP may have a width (e.g., a set or predetermined width) W1. The width W1 is not particularly limited as long as the plurality of trenches TP can be located where they are in contact with the lower surface of the light-emitting element ED. In addition, the trenches TP may have a separation distance (e.g., a set or predetermined separation distance) SD1 from adjacent trenches TP. The separation distance SD1 of the trenches TP may be equal to or greater than the width W1 of the trenches TP. It should be understood, however, that embodiments according to the present disclosure are not limited thereto. The separation distance SD1 of the trenches TP may be smaller than the width W1 of the trenches TP.

The light-emitting element ED may be applied with a solvent onto the first insulating layer PAS1, and then the light-emitting element ED may move by an electric field formed over the first insulating layer PAS1 and seated and aligned on the electrodes RME. According to some embodiments, the trench portions TRP are formed on the first insulating layer PAS1, and thus the light-emitting element ED can be fixed and is not moved to another location due to friction with the trench portions TRP once the light-emitting element ED is seated on the electrodes RME. In other words, by forming the trench portions TRP in the first insulating layer PAS1, the light-emitting element ED can be aligned reliably on the electrodes RME.

The bank layer BNL may be located on the first insulating layer PAS1. The bank layer BNL may include portions extended in the first direction DR1 and the second direction DR2 and may surround each of the sub-pixels SPXn. The bank layer BNL may surround the emission area EMA and the subsidiary area SA of each of the sub-pixels SPXn to distinguish between them, and may surround the border of the display area DPA to distinguish between the display area DPA and the non-display area NDA. The bank layer BNL may be arranged in the entire display area DPA to form a lattice pattern. The area opened by the bank layer BNL in the display area DPA may be the emission area EMA and the subsidiary area SA.

The bank layer BNL may have a height (e.g., a set or predetermined height) similar to the bank patterns BP1 and BP2. In some embodiments, the top surface of the bank layer BNL may have a height higher than that of the bank patterns BP1 and BP2, and the thickness thereof may be equal to or greater than the thicknesses of the bank patterns BP1 and BP2. The bank layer BNL can prevent or reduce instances of an ink overflowing into adjacent sub-pixels SPXn during an inkjet printing process of the process of fabricating the display device 10. The bank layer BNL may include an organic insulating material such as polyimide, like the bank patterns BP1 and BP2.

The plurality of light-emitting elements ED may be located in the emission area EMA. The light-emitting elements ED may be located between the bank patterns BP1 and BP2 and may be spaced apart from one another in the first direction DR1. According to some embodiments of the present disclosure, the plurality of light-emitting elements ED may have a shape extended in one direction, and the both ends to light-emitting elements ED may be located on different electrodes RME, respectively. The length of the light-emitting elements ED may be larger than the distance between the electrodes RME spaced apart from each other in the second direction DR2. The direction in which the light-emitting elements ED are generally extended may be perpendicular to the first direction DR1 in which the electrodes RME are extended. It is, however, to be understood that embodiments according to the present disclosure are not limited thereto. The direction in which the light-emitting elements ED are extended may face the second direction DR2 or a direction obliquely thereto.

The light-emitting elements ED may be located on the first insulating layer PAS1. The light-emitting elements ED may be arranged in contact with the trenches TRP formed on the first insulating layer PAS1. The light-emitting elements ED may be extended in a direction, and the direction may be parallel to the upper surface of the first substrate SUB. As will be described later, the light-emitting elements ED may include a plurality of semiconductor layers arranged in the extended direction. The plurality of semiconductor layers may be sequentially arranged along a direction parallel to the upper surface of the first substrate SUB. It should be understood, however, that embodiments according to the present disclosure are not limited thereto. When the light-emitting elements ED have a different structure, a plurality of semiconductor layers may be arranged in a direction perpendicular to the first substrate SUB.

The light-emitting elements ED located in each of the sub-pixels SPXn may emit light of different wavelength bands depending on the material of the semiconductor layer. It is, however, to be understood that embodiments according to the present disclosure are not limited thereto. The light-emitting elements ED located in each of the sub-pixels SPXn may include the semiconductor layers made of the same material and may emit light of the same color.

The light-emitting elements ED may be electrically connected to the electrodes RME and the conductive layers under the via layer VIA in contact with the connection electrodes CNE: CNE1 and CNE2, and an electric signal may be applied to it so that light of a particular wavelength range can be emitted.

The second insulating layer PAS2 may be located on the light-emitting elements ED and the first insulating layer PAS1. The second insulating layer PAS2 may be extended in the first direction DR1 between the bank patterns BP1 and BP2 and may include a pattern portion located on the plurality of light-emitting elements ED. The pattern portion may be arranged to partially surround the outer surface of the light-emitting elements ED, and may not cover both sides or both ends of the light-emitting elements ED. The pattern portion may form a linear or island pattern in each sub-pixel SPXn when viewed from the top. The pattern portion of the second insulating layer PAS2 can protect the light-emitting elements ED and can fix the light-emitting elements ED during the process of fabricating the display device 10.

The plurality of connection electrodes CNE: CNE1 and CNE2 may be located on the plurality of electrodes RME and the bank patterns BP1 and BP2. The plurality of connection electrodes CNE may each have a shape extended in one direction and may be spaced apart from one another. The connection electrodes CNE may be in contact with the light-emitting elements ED and may be electrically connected to the third conductive layer.

The connection electrodes CNE may include a first connection electrode CNE1 and a second connection electrode CNE2 located in each sub-pixel SPXn. The first connection electrode CNE1 may have a shape extended in the first direction DR1 and may be located on the first electrode RME1 or the first bank pattern BP1. The first connection electrode CNE1 may partially overlap with the first electrode RME1 and may be arranged from the emission area EMA to the subsidiary area SA beyond the bank layer BNL. The second connection electrode CNE2 may have a shape extended in the first direction DR1 and may be arranged on the second electrode RME2 or the second bank pattern BP2. The second connection electrode CNE2 may partially overlap with the second electrode RME2 and may be arranged from the emission area EMA to the subsidiary area SA beyond the bank layer BNL. The first connection electrode CNE1 and the second connection electrodes CNE2 may be in contact with the light-emitting elements ED and may be electrically connected to the electrodes RME or a conductive layer thereunder.

For example, the first connection electrode CNE1 and the second connection electrode CNE2 may be located on the side surfaces of the second insulating layer PAS2, respectively, and may be in contact with the light-emitting elements ED. The first connection electrode CNE1 may partially overlap with the first electrode RME1 and may be in contact with first ends of the light-emitting elements ED. The second connection electrode CNE2 may partially overlap with the second electrode RME2 and may be in contact with second ends of the light-emitting elements ED. The plurality of connection electrodes CNE are arranged across the emission area EMA and the subsidiary area SA. A portion of each of the connection electrodes CNE that is located in the emission area EMA may be in contact with the light-emitting elements ED, and a part thereof that is located in the subsidiary area SA may be electrically connected to the third conductive layer.

In the display device according to some embodiments, each of the connection electrodes CNE may be in contact with the electrodes RME through the contacts CT1 and CT2 located in the subsidiary area SA. The first connection electrode CNE1 may be in contact with the first electrode RME1 through the first contact CT1 penetrating the first insulating layer PAS1 and the second insulating layer PAS2 in the subsidiary area SA. The second connection electrode CNE2 may be in contact with the second electrode RME1 through the second contact CT2 penetrating the first insulating layer PAS1 and the second insulating layer PAS2 in the subsidiary area SA. As described above, the contacts CT1 and CT2 may be formed by simultaneously etching the first insulating layer PAS1 and the second insulating layer PAS2. According to some embodiments, the first insulating layer PAS1 contains silicon oxynitride that has the etch selectivity of 4.1 or more with respect to the second insulating layer PAS2, so that the contacts CT1 and CT2 can be easily formed.

The connection electrodes CNE may be electrically connected to the third conductive layer through the respective electrodes RME. The first connection electrode CNE1 may be electrically connected to the first transistor T1 to apply the first supply voltage, and the second connection electrode CNE2 may be electrically connected to the second voltage line VL2 to apply the second supply voltage. Each of the connection electrodes CNE may be in contact with the light-emitting elements ED in the emission area EMA to transmit the supply voltage to the light-emitting elements ED.

It is, however, to be understood that embodiments according to the present disclosure are not limited thereto. In some embodiments, the plurality of connection electrodes CNE may be in direct contact with the third conductive layer, or may be electrically connected to the third conductive layer through other patterns than the electrodes RME.

The connection electrodes CNE may include a conductive material. For example, the connection electrodes CNE may include ITO, IZO, ITZO, aluminum (AI), etc. For example, the connection electrodes CNE may include a transparent conductive material, and lights emitted from the light-emitting elements ED may transmit the connection electrodes CNE to exit.

According to some embodiments, another insulating layer may be further located on the first connection electrode CNE1, the second connection electrode CNE2 and the second insulating layer PAS2. The insulating layer can protect the elements located on the first substrate SUB against the external environment.

Each of the first insulating layer PAS1 and the second insulating layer PAS2 may include an inorganic insulating material or an organic insulating material. For example, each of the first insulating layer PAS1 and the second insulating layer PAS2 may include an inorganic insulating material, or the first insulating layer PAS1 may include an inorganic insulating material while the second insulating layer PAS2 may include an organic insulating material. Either both or one of the first insulating layer PAS1 and the second insulating layer PAS2 may be formed in a structure in which insulating layers are alternately or repeatedly stacked on one another. According to some embodiments of the present disclosure, each of the first insulating layer PAS1 and the second insulating layer PAS2 may be made of one of silicon oxide (SiOx), silicon nitride (SiNx), and silicon oxynitride (SiOxNy). The first insulating layer PAS1 and the second insulating layer PAS2 may be made of the same material. Alternatively, some of them may be made of the same material while the other(s) may be made of different material(s), or they may be made of different materials.

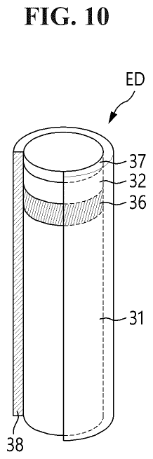

FIG. 10 is a view showing a light-emitting element according to some embodiments of the present disclosure.

Referring to FIG. 10, a light-emitting element ED may be a light-emitting diode. Specifically, the light-emitting element ED may have a size from nanometers to micrometers and may be an inorganic light-emitting diode made of an inorganic material. The light-emitting element ED may be aligned between two electrodes facing each other as polarities are created by forming an electric field in a particular direction between the two electrodes.

The light-emitting element ED according to some embodiments may have a shape extended in one direction. The light-emitting element ED may have a shape of a cylinder, a rod, a wire, a tube, etc. It is to be understood that the shape of the light-emitting element ED is not limited thereto. The light-emitting element ED may have a variety of shapes including a polygonal column shape such as a cube, a cuboid and a hexagonal column, or a shape that is extended in a direction with partially inclined outer surfaces.

The light-emitting element ED may include semiconductor layers doped with a dopant of a conductive type (e.g., p-type or n-type). The semiconductor layers may emit light of a certain wavelength band by transmitting an electric signal applied from an external power source. The light-emitting diode ED may include a first semiconductor layer 31, a second semiconductor layer 32, an emissive layer 36, an electrode layer 37, and an insulating film 38.

The first semiconductor layer 31 may be an n-type semiconductor. The first semiconductor layer 31 may include a semiconductor material having the following chemical formula: AlₓGa_{y}In_{1-x-y}N (0≤x≤1, 0≤y≤1, 0≤x+y≤1). For example, the first semiconductor layer 31 may be one or more of AlGaInN, GaN, AlGaN, InGaN, AlN and InN doped with n-type dopant. The n-type dopant doped into the first semiconductor layer 31 may be Si, Ge, Se, Sn, etc.

The second semiconductor layer 32 is located above the first semiconductor layer 31 with the emissive layer 36 therebetween. The second semiconductor layer 32 may be a p-type semiconductor, and may include a semiconductor material having the following chemical formula: AlₓGa_{y}In_{1-x-y}N (0≤x≤1, 0≤y≤1, 0≤x+y≤1). For example, the second semiconductor layer 32 may be one or more of AlGaInN, GaN, AlGaN, InGaN, AlN and InN doped with p-type dopant. The p-type dopant doped into the second semiconductor layer 32 may be Mg, Zn, Ca, Ba, etc.

Although each of the first semiconductor layer 31 and the second semiconductor layer 32 is implemented as a signal layer in the drawings, embodiments according to the present disclosure are not limited thereto. Depending on the material of the emissive layer 36, the first semiconductor layer 31 and the second semiconductor layer 32 may further include a larger number of layers, e.g., a clad layer or a tensile strain barrier reducing (TSBR) layer. For example, the light-emitting elements ED may further include another semiconductor layer located between the first semiconductor layer 31 and the emissive layer 36 or between the second semiconductor layer 32 and the emissive layer 36. The semiconductor layer located between the first semiconductor layer 31 and the emissive layer 36 may be one or more of AlGaInN, GaN, AlGaN, InGaN, AlN, InN and SLs doped with an n-type dopant. The semiconductor layer located between the second semiconductor layer 32 and the emissive layer 36 may be one or more of AlGaInN, GaN, AlGaN, InGaN, AlN, and InN doped with a p-type dopant.

The emissive layer 36 is located between the first semiconductor layer 31 and the second semiconductor layer 32. The emissive layer 36 may include a material having a single or multiple quantum well structure. When the emissive layer 36 includes a material having the multiple quantum well structure, the structure may include quantum layers and well layers alternately stacked on one another. The emissive layer 36 may emit light as electron-hole pairs are combined therein in response to an electrical signal applied through the first semiconductor layer 31 and the second semiconductor layer 32. The emissive layer 36 may include a material such as AlGaN, AlGaInN, and InGaN. In particular, when the emissive layer 36 has a multi-quantum well structure in which quantum layers and well layers are alternately stacked on one another, the quantum layers may include AlGaN or AlGaInN, and the well layers may include a material such as GaN and AlGaN.

The emissive layer 36 may have a structure in which a semiconductor material having a large band gap energy and a semiconductor material having a small band gap energy are alternately stacked on one another, and may include other Group III to Group V semiconductor materials depending on the wavelength range of the emitted light. Accordingly, the light emitted from the emissive layer 36 is not limited to the light of the blue wavelength band. The emissive layer 36 may emit light of red or green wavelength band in some implementations.

The electrode layer 37 may be an ohmic connection electrode. It is, however, to be understood that embodiments according to the present disclosure are not limited thereto. The electrode layer 37 may be a Schottky connection electrode. The light-emitting element ED may include at least one electrode layer 37. The light-emitting element ED may include one or more electrode layers 37. It is, however, to be understood that embodiments according to the present disclosure are not limited thereto. The electrode layer 37 may be eliminated.

The electrode layer 37 can reduce the resistance between the light-emitting element ED and the electrodes or the connection electrodes when the light-emitting element ED is electrically connected to the electrodes or the connection electrodes in the display device 10. The electrode layer 37 may include a metal having conductivity. For example, the electrode layer 37 may include at least one of aluminum (Al), titanium (Ti), indium (In), gold (Au), silver (Ag), ITO, IZO, or ITZO.

The insulating film 38 is arranged to surround the outer surfaces of the plurality of semiconductor layers and electrode layers described above. For example, the insulating film 38 may be arranged to surround at least the outer surface of the emissive layer 36, with both ends of the light-emitting element ED in the longitudinal direction exposed. In addition, a portion of the upper surface of the insulating film 38 may be rounded in cross section, which is adjacent to at least one of the ends of the light-emitting element ED.

The insulating film 38 may include materials having insulating properties, for example, at least one of: silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx). Although the insulating film 38 is formed as a single layer in the drawings, embodiments according to the present disclosure are not limited thereto. In some embodiments, the insulating film 38 may be made up of a multilayer structure in which multiple layers are stacked on one another.

The insulating film 38 can protect the semiconductor layers and the electrode layer of the light-emitting elements ED. The insulating film 30 can prevent or reduce an electrical short-circuit that may occur in the emissive layer 36 if it comes in direct contact with an electrode through which an electric signal is transmitted to the light-emitting diode ED. In addition, the insulating film 38 can prevent or reduce a decrease in luminous efficiency.

In addition, the outer surface of the insulating film 38 may be subjected to surface treatment. The light-emitting elements ED may be dispersed in an ink, and the ink may be sprayed onto the electrode. In doing so, a surface treatment may be applied to the insulating film 38 so that it becomes hydrophobic or hydrophilic in order to keep the light-emitting elements ED dispersed in the ink from being aggregated with one another.

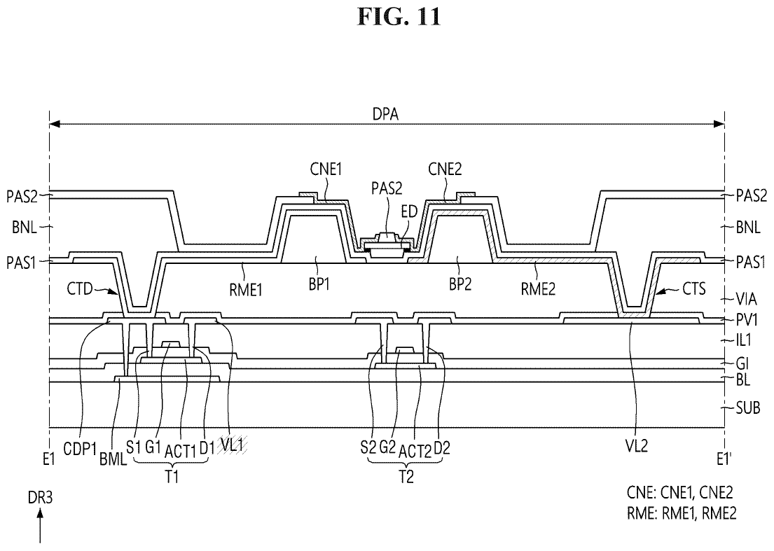

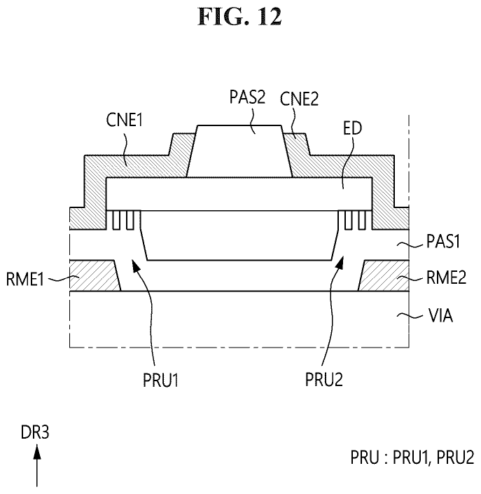

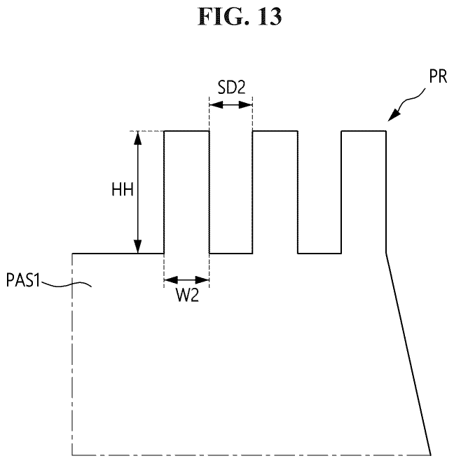

FIG. 11 is a cross-sectional view showing a display device according to some embodiments of the present disclosure. FIG. 12 is an enlarged view of a portion of FIG. 11. FIG. 13 is a view showing protrusions of a first insulating layer.

The embodiments illustrated with respect to FIGS. 11 to 13 are substantially identical to the embodiments illustrated with respect to FIG. 5 except that a first insulating layer PAS1 includes protrusion portions PRU; and, therefore, some redundant descriptions will be omitted.

The first insulating layer PAS1 may include protrusion portions PRU. The protrusion portions PRU may be portions protruding toward a light-emitting element ED from the surface of the first insulating layer PAS1. The protrusion portions TRP may be formed as one body with the first insulating layer PAS1 and may be a portion of the first insulating layer PAS1. It should be understood, however, that embodiments according to the present disclosure are not limited thereto. The protrusion portions PRU may be formed separately from the first insulating layer PAS1. The protrusion portions PRU may be located under the light-emitting element ED when viewed from the top and can relatively improve adhesion of the light-emitting element ED by inducing physical surface friction with the light-emitting element ED.

The protrusion portions PRU may include a first protrusion portion PRU1 and a second protrusion portion PRU2. The first protrusion portion PRU1 may overlap with a first electrode RME1 and one end of the light-emitting element ED. The second protrusion portion PRU2 may overlap with a second electrode RME2 and the other end of the light-emitting element ED. The first protrusion portion PRU1 and the second protrusion RPU2 may be extended in the first direction DR1 and may be spaced apart from each other in the second direction DR2. The first protrusion portion PRU1 and the second protrusion portion PRU2 may be arranged parallel to each other.

Each of the first protrusion portion PRU1 and the second protrusion portion PRU2 may be in contact with the light-emitting element ED. For example, the first protrusion portion PRU1 may be in contact with the lower surface of one end of the light-emitting element ED, and the second protrusion portion PRU2 may be in contact with the lower surface of the other end of the light-emitting element ED. The first protrusion portion PRU1 and the second protrusion portion PRU2 may be located within the length of the light-emitting element ED where they overlap with the light-emitting element ED. For example, the width of the first protrusion portion PRU1 in the second direction DR2 may be smaller than the length of the light-emitting element ED. Likewise, the width of the second protrusion portion PRU2 in the second direction DR2 may be smaller than the length of the light-emitting element ED. The sum of the width of the first protrusion portion PRU1 and the width of the second protrusion portion PRU2 may be smaller than the length of the light-emitting element ED.

In addition, the side of the first protrusion portion PRU1 and the side of one end of the light-emitting element ED may be aligned with each other. If the first protrusion portion PRU1 is located more to the outside than the side of one end of the light-emitting element ED, the light reflected off the electrodes RME is reflected and diffused between protrusions PR of the first protrusion portion PRU1, reducing the emission efficiency.

Each of the first protrusion portion PRU1 and the second protrusion portion PRU2 may include a plurality of protrusions PR. The protrusions PR may be extended in the first direction DR1 and may be spaced apart from one another in the second direction DR2. The protrusions PR may have a height HH of 1 to 30% of the thickness of the first insulating layer PAS1. The protrusions PR may have a width (e.g., a set or predetermined width) W2. The width W2 is not particularly limited as long as the plurality of protrusions PR can be arranged where they are in contact with the lower surface of the light-emitting element ED. In addition, the protrusions PR may have a separation distance (e.g., a set or predetermined separation distance) SD2 from adjacent protrusions PR. The separation distance SD2 of the protrusions PR may be equal to or greater than the width W2 of the protrusions PR. It should be understood, however, that embodiments according to the present disclosure are not limited thereto. The separation distance SD2 of the protrusions PR may be less than the width W2 of the protrusions PR.

As described above, the light-emitting element ED may be applied with a solvent onto the first insulating layer PAS1, and then the light-emitting element ED may move by an electric field formed over the first insulating layer PAS1 and seated and aligned on the electrodes RME. According to some embodiments, the protrusion portions PRU are formed on the first insulating layer PAS1, and thus the light-emitting element ED can be fixed and is not moved to another location due to friction with the protrusion portions PRU once the light-emitting element ED is seated on the electrodes RME. In other words, by forming the protrusion portions PRU in the first insulating layer PAS1, the light-emitting element ED can be aligned reliably on the electrodes RME.

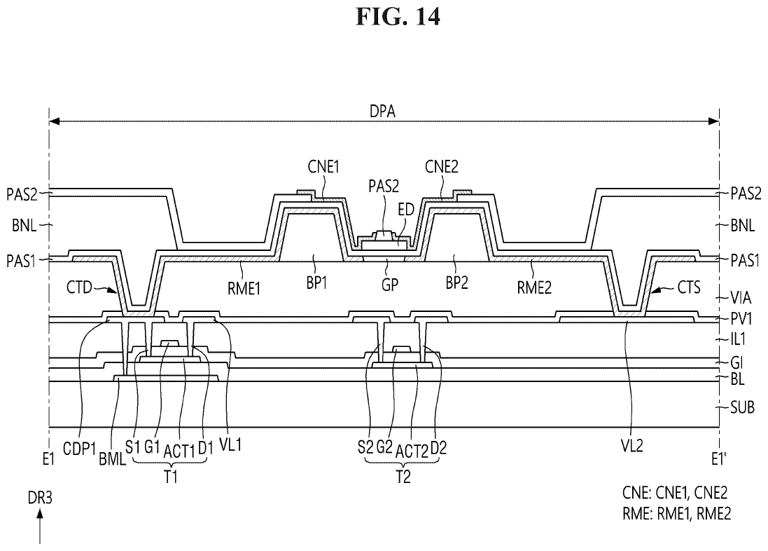

FIG. 14 is a cross-sectional view showing a display device according to some embodiments of the present disclosure.

The embodiments illustrated with respect to FIG. 14 are substantially identical to the embodiments illustrated with respect to FIGS. 5 to 13 except that a planarization layer GP is located between electrodes RME, and, therefore, some redundant descriptions of similar components may be omitted.

The planarization layer GP may be located between the electrodes RME. For example, the planarization layer GP may be located between a first electrode RME1 and a second electrode RME2. The planarization layer GP may be located on the upper surface of the via layer VIA and may be arranged in contact with the side surface of each of the first electrode RME1 and the second electrode RME2. The planarization layer GP may fill the space between the first electrode RME1 and the second electrode RME2. The upper surface of the planarization layer GP may be aligned with the upper surface of the first electrode RME1 and the upper surface of the second electrode RME2.

The planarization layer GP may be made of an organic insulating material such as polyimide. For example, the planarization layer GP may be made of the same material as the via layer VIA, bank patterns BP1 and BP2, or a bank layer BNL.

The first insulating layer PAS1 may be arranged on the planarization layer GP and may overlap with the light-emitting element ED. The planarization layer GP may provide a flat surface under the first insulating layer PAS1 so that the first insulating layer PAS1 is flat where it overlaps with the light emitting element ED. While the sides of each of the first electrode RME1 and the second electrode RME2 are tapered, the sides of the first electrode RME1 and the second electrode RME2 may be filled with the planarization layer GP, so that the step may be eliminated. In this manner, the first insulating layer PAS1 formed on the first electrode RME1 and the second electrode RME2 can be formed flat, thereby preventing or reducing a seam in the first insulating layer PAS1.

Hereinafter, Experimental Example for the first insulating layer according to some embodiments will be described in more detail.

### Experimental Example: Occurrence of Seam Depending on Composition of First Insulating Layer

### Example

An electrode was formed on a substrate, and a first insulating layer covering the electrode was formed on the electrode. Subsequently, a first connection electrode was formed on the first insulating layer. The electrode was made of an aluminum alloy, and the first connection electrode was stacked using ITO.

### Comparative Example 1

A film was formed of SiOx with the thickness of 3,000 Å as a first insulating layer.

### Comparative Example 2

A film was formed of SiON with the thickness of 3,000 Å as a first insulating layer. The composition ratios were 34.6 at % for Si, 63.8 at % for O, and 1.5 at % for N.

### Comparative Example 3

A film was formed of SiON with the thickness of 3,000 Å as a first insulating layer. The composition ratios were 42.9 at % for Si, 24.2 at % for O, and 32.9 at % for N.

### Example Embodiments

A film was formed of SiON with the thickness of 3,000 Å as a first insulating layer. The composition ratios were 41.8 at % for Si, 29.0 at % for O, and 29.3 at % for N.

The structures produced according to Comparative Examples 1 to 3 and Embodiments described above were observed using a transmission electron microscope (TEM) to obtain the images.

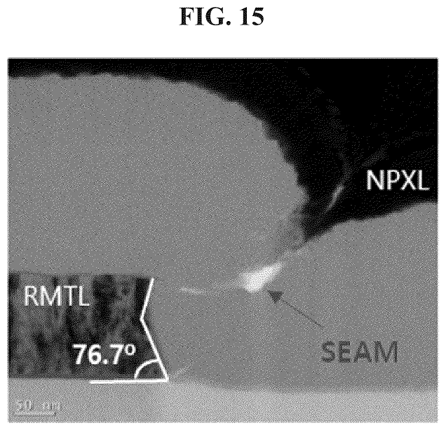

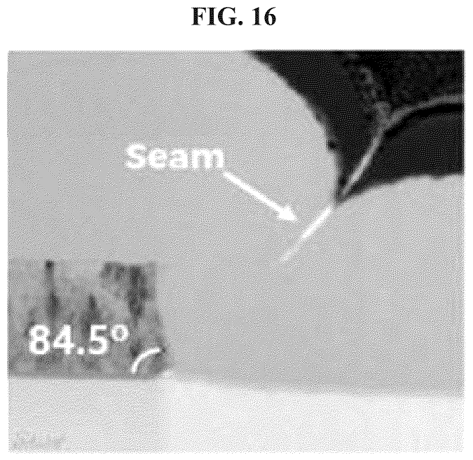

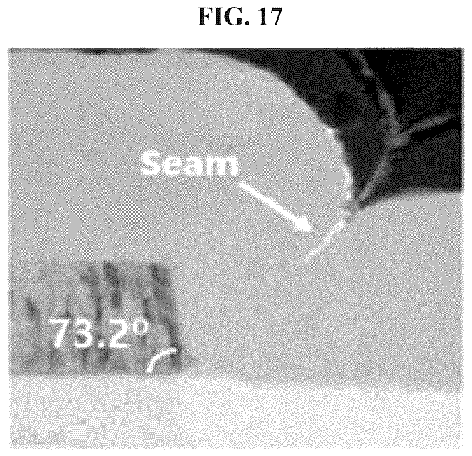

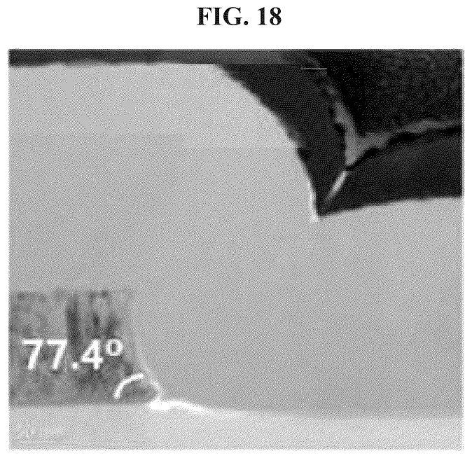

FIG. 15 is an image taken by a transmission electron microscope according to Comparative Example 1. FIG. 16 is an image taken by the transmission electron microscope according to Comparative Example 2. FIG. 17 is an image taken by the transmission electron microscope according to Comparative Example 3. FIG. 18 is an image taken by the transmission electron microscope according to the Example Embodiments.

Referring to FIGS. 15 to 18, seams were found in all of the first insulating layers according to Comparative Examples 1 to 3. On the contrary, no seam was found in the first insulating layer according to the Example Embodiments.

It can be seen from the results that the first insulating layer according to some embodiments contains silicon oxynitride with the composition ratios of Si, O and N adjusted, and thus it may be possible to prevent or reduce seams on the side surfaces of the electrodes.

In concluding the detailed description, those skilled in the art will appreciate that many variations and modifications can be made to the example embodiments without substantially departing from the spirit and scope of embodiments according to the present invention. Therefore, the disclosed example embodiments of the invention are used in a generic and descriptive sense only and not for purposes of limitation.

What is claimed is:

1. A display device comprising:
a substrate;
a first electrode and a second electrode on the substrate, extended in a first direction and spaced apart from each other;
a first insulating layer on the first electrode and the second electrode;
a light-emitting element on the first insulating layer and between the first electrode and the second electrode; and
a first connection electrode connected to a first end of the light-emitting element and a second connection electrode connected to a second end of the light-emitting element,
wherein the first insulating layer overlaps with the light-emitting element and comprises trench portions comprising a plurality of trenches.

2. The display device of claim 1, wherein the trench portions comprise a first trench portion overlapping with the first end of the light-emitting element, and a second trench portion overlapping with the second end of the light-emitting element.

3. The display device of claim 2, wherein the first trench portion overlaps with the first electrode and extends in parallel with the first electrode, and wherein the second trench portion overlaps with the second electrode and extends in parallel with the second electrode.

4. The display device of claim 2, wherein a side of the first trench portion is aligned with and coincides with a side of the first end of the light-emitting element, and a side of the second trench portion is aligned with and coincides with a side of the second end of the light-emitting element.

5. The display device of claim 1, wherein the trench portions contact a lower surface of the light-emitting element.

6. The display device of claim 1, wherein a depth of the trenches is in a range of 1% to 30% of a thickness of the first insulating layer.

7. The display device of claim 1, wherein the first insulating layer contains silicon oxynitride represented by the following chemical formula:
SixOyNz
wherein x, y and z satisfy 34.6<x<42.9, 24.2<y<63.8 and 1.5<z<32.9, respectively, and x, y and z denote atomic ratios.

8. The display device of claim 1, wherein a thickness of the first insulating layer is in a range of 2,000 Å to 3,000 Å.

9. The display device of claim 1, wherein a refractive index of the first insulating layer is in a range of greater than 1.4 and less than 1.63.

10. The display device of claim 1, further comprising:
a second insulating layer on the light-emitting element, wherein an etch selectivity of the first insulating layer with respect to the second insulating layer is 4.1 or more.

11. A display device comprising:
a substrate;
a first electrode and a second electrode on the substrate, extending in a first direction and spaced apart from each other;
a first insulating layer on the first electrode and the second electrode;
a light-emitting element on the first insulating layer and between the first electrode and the second electrode; and
a first connection electrode connected to a first end of the light-emitting element and a second connection electrode connected to a second end of the light-emitting element,
wherein the first insulating layer overlaps with the light-emitting element and comprises protrusion portions comprising a plurality of protrusions.

12. The display device of claim 11, wherein the protrusion portions comprise a first protrusion portion overlapping with the first end of the light-emitting element, and a second protrusion portion overlapping with the second end of the light-emitting element.

13. The display device of claim 12, wherein the first protrusion portion overlaps with the first electrode and extends in parallel with the first electrode, and wherein the second protrusion portion overlaps with the second electrode and extends in parallel with the second electrode.

14. The display device of claim 12, wherein a side of the first protrusion portion is aligned with and coincides with a side of the first end of the light-emitting element, and a side of the second protrusion portion is aligned with and coincides with a side of the second end of the light-emitting element.

15. The display device of claim 11, wherein the protrusion portions contact a lower surface of the light-emitting element.

16. The display device of claim 11, wherein a height of the protrusions is in a range of 1% to 30% of a thickness of the first insulating layer.

17. The display device of claim 11, wherein the first insulating layer contains silicon oxynitride represented by the following chemical formula:
SixOyNz
wherein x, y and z satisfy 34.6<x<42.9, 24.2<y<63.8 and 1.5<z<32.9, respectively, and x, y and z denote atomic ratios.

18. The display device of claim 11, wherein a thickness of the first insulating layer is in a range from 2,000 Å to 3,000 Å.

19. The display device of claim 11, wherein a refractive index of the first insulating layer is in a range of greater than 1.4 and less than 1.63.

20. The display device of claim 11, further comprising:
a second insulating layer on the light-emitting element,
wherein an etch selectivity of the first insulating layer with respect to the second insulating layer is 4.1 or more.
